(19) United States
(12) Patent Application Publication
(10) Pub. No.: US 2010/0231243 A1
(43) Pub. Date: Sep. 16, 2010

(54) Electrode holder for use on cattle and the like and on their carcasses

(76) Inventors: Neal S. Latman, Amarillo, TX (US); Joseph E. Batson, JR., Amarillo, TX (US); Alan Nicholson, Canyon, TX (US); Ladislado Garza, Amarillo, TX (US); Mike Floyd, Amarillo, TX (US)

Correspondence Address: Harold H. Flanders, 904 Sweetwater Cove, Round Rock, TX, 78681, US

(21) Appl. No.: 12/381,333

(22) Filed: Mar. 11, 2009

(51) Int. Cl. G01N 27/04; G01D 21/00; G01R 27/08

(52) U.S. Cl. 324/693; 73/866.5

(57) ABSTRACT

An electrode holder comprising a deck member with handle supporting a pair of penetrating electrodes to which a hypodermic syringe or needles may be connected and which may act as electrodes in a BIA system and/or in connection with making other electrical measurements.

### BACKGROUND OF THE INVENTION

1. Field of the Invention

The present invention relates generally to a process applicable to electrodes and systems for holding electrodes and more particularly to a new and improved method for the use of such electrodes and holders in connection with cattle and the like and their carcasses using Bioelectrical Impedance Analysis (BIA), and for such other structure, apparatus, processes, systems, and methods as may be herein disclosed.

The present invention is and may be used in connection with measurements requiring the use of electrodes as described herein and in general.

As a specific example reference is made to Bioelectrical Impedance Analysis (BIA). The initials or acronym BIA may refer to one or more of several slightly different terms all of which may be considered to be equivalent as discussed below and used herein. The meaning is almost always clear from the context of use and for the purposes of this application these terms may in general be used interchangeably. The term Bioelectrical Impedance Analysis is generally preferred and used herein as it conveys the most information in its terms. Other generally equivalent terms which may be used include Bioimpedance Analysis or BioImpedance Analysis, Biological Impedance Analysis, Biological Impedance Interface, Electrical Bio-impedance, Electrical Impedance Analysis, and similar terms and combination of terms.

2. Relevant State of the Art and Description of Related Prior Art

As has been noted above, the present invention relates to electrodes in general and especially to measurements as may be required on cattle and their carcasses.

Cattle are important animals having significant economic, and agricultural significance. Various measurements may be made or desired relating to their development, use, and breeding. Similar concerns and measurements may be made on other animals.

Among the measurements of particular interest are those known as bioelectrical impedance analysis, although as has been noted the present invention is not limited to such specific measurements or techniques.

Bioelectrical Impedance Analysis may be used to measure and analyze a wide range of ionic and charge transfer processes in bio-materials and biological systems in general.

As a matter of general background to the present invention, it may be helpful to note the following terms:

Electricity is the movement of electrons.

Electrons have a negative charge. Free electrons will flow or move towards a positive charge or down an electrical gradient towards a less negative charge.

Amperes (Amps) is the number of free electrons flowing or moving per unit time. Sometimes this flow of electrons is referred to as “Intensity” or “I”. Sometimes this flow is referred to as “electrical current”. In many situations, it may be best to think about amperes as the amount of or volume of electrons that are moving per unit of time. One ampere=6.25×10¹⁸ electrons per second.

Conductors: The flow of electrons moves along a material or substance called a “conductor”. Some substances offer more or less resistance to the flow of electrons than others. Those that offer little resistance to the flow of electrons are considered “good conductors” A good conductor is a material that has electrons that are less tightly bound and therefore, more free to move. In a bad conductor, the electrons are more tightly bound and less free to move. A really bad conductor is called an “insulator”.

Volts represent the potential difference in charges between two points in or along a conductor. That means that there is an electrical gradient between the two points. In other words, there are more negative charges (electrons) at one point than at the other. The more positively charged point would exert an attractive force or pull on the electrons toward it. The attractive force is called an “electromotive force”.

The relationship between amperes, volts and resistance to flow of electrons may be expressed by Ohm's law: Volts=Amperes×Resistance in Ohms. All conductors offer some resistance to the flow of electrons.

A “capacitor in an electric circuit is a non-conductor (insulator, sometimes called a “dielectric”) that is sandwiched between two conductors. As the electrons flow down the conductor, it comes to the capacitor. Because the capacitor is a non-conductor, the electrons begin to pile-up on one side of it. As more negatively charged electrons accumulate, the potential electrical difference between the negative side of the capacitor and the relatively positively charged side increases. Like charges repel each other. So, as the negatively charged electrons accumulate on one side of the capacitor, the increasing negative charge on that side of the capacitor repels the negatively charged electrons on the other side of the capacitor. That results in one side of the capacitor with more electrons next to the capacitor than the other side. When the potential difference in negative electrons between the two sides is sufficiently great, the electrons on the relatively less negative side of the capacitor begin to move away from the capacitor and down the conductor. We can view a capacitor as a non-conductor that results in an increase in voltage.

Sometimes, capacitance is thought of as the amount of electrons necessary to raise the potential by a specific amount. At other times, capacitance may be thought of as the amount of electrons that can be “stored” on a surface (i.e., the negative side of the capacitor), before the electrical current moves on. Capacitance is measured in “Farads”.

A cell membrane is composed of a biomolecular layer of phospholipids. Lipids are poor electrical conductors. They are so poor as to be viewed as non-conductors. When an electrical current flows through the fluids in the body (a relatively good conductor) and comes to a cell membrane such as a red blood cell, the cell membrane acts as a capacitor, the capacitance of which can be measured.

Bioelectrical Impedance Analysis (BIA) measures the impedance or opposition to the flow of electrical current through body fluids. Impedance is low in lean tissue where intracellular fluid and electrolytes are primarily contained, but high in fat tissue. Impedance is generally proportional to body water volume. In practice, a small constant current, typically 800 uA at a fixed frequency, for example 50 kHz, is passed between electrodes spanning the body parts in question and the voltage drop between electrodes provides a measure of impedance.

The impedance of a biological tissue comprises two components, the resistance and the reactance. The conductive characteristics of body fluids provide the resistive component, whereas the cell membranes, acting as imperfect capacitors, contribute a frequency-dependent reactive component.

Impedance measurements made over a range of low to high (1 MHz) frequencies, allow the development of predictive equations. For example, equations may relate impedance measures at low frequencies to extracellular fluid volumes and at high frequencies to total body fluid volume. This approach is known a multi-frequency bioelectrical impedance analysis (MFBIA).

The BIA measurements in general involve the measurement of:
a.) resistance in ohms {“R”}
b.) reactance in ohms {“Xc”} [basically defined as the opposition to transmission of electrical energy through a capacitor.]
c.) impedance in ohms {“Z”} [basically defined as Z=√[R²+(Xc)²] (i.e. the square root of [R squared+Xc squared]).

The above paraphrased from tutorial papers of Dr. Neal Latman and from pp. 29-32 Horowitz & Hill, The Art of Electronics (2d Ed.) Cambridge University Press, Cambridge, Mass., 1989.

Further background for the present invention is set forth in Marchello, M. J. and W. D. Slanger; “Bioelectrical Impedance Can Preselect Skeletal Muscle and Fat-Free Skeletal Muscle of Beef Cows and Their Carcasses;” J. Am. Sci. 1994, 721:3118-3123.

See also, Marchello, M. J., J. E. McLennan; D. V. Dhuyvetter; and W. D. Slanger; “Determination of Saleable Product in Finished Cattle and Beef Carcasses Utilizing Bioelectrical Impedance Technology;” J. Anim. Sci; 1999.77:2965-2970.

Further background of the present invention is provided by Forro, Mariam, Scott Cieslar, Gayle L. Ecker, Angela Walzak, Joy Hahn, and Michael I. Lindenger, “Total body water and ECFV measured using bioelectrical impedance analysis and indicator dilution in horses”: J. Appl Physiol 89: 663*671,2000. which to some extent appears to teach away from the present invention, see sections on the linear regression analysis.

Also see, Fielding, C. Langdon, Gary Magdesean, Denise A. Elliott, Larry D. Cowgell, and Gary P. Carlson; “Use of multifrequency bioelectrical impedance analysis for estimation of total body water and extracellular and intracellular fluid volumes in horses”, AJVR, Vol 65, No. 3, 320, 326 March 2004.

See also U.S. Pat. No. 6,850,798 which measures animal body fat via the hooves and foot pads; U.S. Pat. Nos. 6,308,096 and 6,321,112 at their FIG. 25 and 2001/0007055 which purports to measure fatigue see FIG. 12.

U.S. Pat. No. 6,360,124 is handheld and U.S. Pat. No. 6,400,983 which employs hand electrodes.

U.S. Pat. No. 6,477,409 measures metabolism and U.S. Pat. No. 6,487,445 utilizes calipers.

U.S. Pat. Nos. 6,490,481; 6,509,748; and 2003/0216665 employ multiple electrodes with other body data while U.S. Pat. Nos. 6,516,221 and 6,725,089 feature graphic displays.

U.S. Pat. No. 6,567,692 utilizes multiple sites, U.S. Pat. No. 6,621,013 selects body information to be evaluated.

2003/0176808 allows for multiple fat layers.

2004/0019292 permits use in identification.

2004/0171963 and 2005/0059902 focus on body composition and 2004/0236245 on muscle mass.

2005/0124909 is directed to the measurement of body fat in animals.

U.S. Pat. No. 6,978,170 focuses on electrode positioning.

2006/0094979 and 2006/0111645 utilize multiple pairs of electrode systems.

Other references of interest include: U.S. Pat. Nos. 3,602,215; 3,851,641; 3,871,359; 3,971,365; 4,008,712; 4,116,231; 4,336,873; 4,377,170; 4,423,792; 4,144,763; 4,557,271; 4,557,271; 4,493,362; 4,578,635; 4,557,271; 4,773,492; 4,831,242; 4,831,527; 4,844,187; 4,947,862; 4,805,621; 4,895,163; 4,911,175; 4,919,145; 4,947,862; 5,063,937; 5,086,781; 5,203,344; 5,579,782; 6,088,615; 6,208,890; 5,722,396; 5,819,741; 6,004,312; 6,188,925; 6,280,396; 6,308,096; 6,354,996; 6,370,425; 6,393,317; 6,400,983; 4,949,727; 5,052,405; 5,105,825; 5,372,141; 5,458,117; 5,720,296; 5,746,214; 5,817,031; 5,840,042; 6,151,523; 6,198,964; 6,256,532; 6,265,882; 5,483,970; 5,335,667; 5,415,176; 5,435,3115; 5,449,000; 5,595,189; 5,611,351; 5,615,689; 5,749,369; 5,335,667; 5,817,031; 6,088,615; 6,292,690; 2002/0026173; U.S. Pat. Nos. 6,370,425; 6,393,317; 2002/0151815; U.S. Pat. No. 6,473,643; 2002/0151311; U.S. Pat. No. 6,631,292; 2004/0002662; U.S. Pat. Nos. 5,088,489; 5,335,667; 5,718,850; 5,720,296; 5,729,905; 6,038,465; 6,088,615; 6,321,112; 6,398,740; 6,440,068; 6,327,495; 5,371,469; 5,483,970; 5,503,157; 5,865,763; 6,011,992; 6,339,722; 6,442,422; 6,450,955; 6,490,481; 6,487,445; 6,516,221; 6,526,315; 6,567,692; 5,579,782; 5,819,741; 6,004,312; 6,168,563; 6,280,396; 6,308,096; 6,685,654; 2004/0077968; U.S. Pat. No. 6,752,760; 2004/0260196; U.S. Pat. No. 6,865,415; 2005/0059903/; 2005/0080352; U.S. Pat. No. 6,889,076; 2005/0101875; 2005/0171451; 2005/0177060; 2005/0177062; 2005/0192488; 2005/0209528; 2006/0025701; 2006/0094978.

While a number of Biological Impedance Analysis (BIA) systems are shown and taught by the above art, they, in general, fail to recognize the importance of the electrode system and its critical significance.

### BRIEF SUMMARY OF THE INVENTION

The present invention relates to electrodes and electrode holders for use in connection with beef, cattle, and their carcasses.

The present invention may be used for information relative to salability, treatment of disease and illness and in the selection of breeding stock.

The present invention while designed primarily for use with cattle and their carcasses can be used with other animals including but not limited to, sheep, goats, hogs and dogs.

The present invention can be utilized to measure, or to be a part of a system to measure or evaluate such parameters as total body water, extra and intra-cellular fluid, plasma, lean muscle mass, fat, the extent of marbling, percentage of saleable retail cuts, fat trim yield, percentage fat trim, yield grade, quality grade, percentage saleable meat yield, phase angles, and general, overall health.

### Objects

Pursuant to the foregoing, it may be regarded as an object of the present invention to overcome the deficiencies of and provide for improvements in the state of the prior art as described above and as may be inherent in the same or as may be known to those skilled in the art.

It is a further object of the present invention to provide a process and any necessary apparatus for carrying out the same and of the forgoing character and in accordance with the above objects which may be readily carried out with and within the process and with comparatively simple equipment and with relatively simple engineering requirements.

Still further objects may be recognized and become apparent upon consideration of the following specification, taken as a whole, in conjunction with the appended drawings and claims, wherein by way of illustration and example, an embodiment of the present invention is disclosed.

As used herein, any reference to an object of the present invention should be understood to refer to solutions and advantages of the present invention which flow from its conception and reduction to practice and not to any a priori or prior art conception

The above and other objects of the present invention are realized and the limitations of the prior art are overcome by providing a new and improved method and process applicable to measurements to be made on animals such as cattle and their carcasses.

### Technical Problems to be Solved

The need for an electrode and electrode holding system to provide accurate, reliable and repeatable measurements has long existed and been an unfulfilled need prior to the invention of the present apparatus and process.

In particular, the uneven topographic surfaces presented by certain animals such as cattle and the like over uneven muscles and bone structures have long presented a problem of obtaining accurate and reproducible measurements in various electrical systems including those directed to bioelectrical impedance analysis.

### BRIEF DESCRIPTION OF THE DRAWINGS AND THEIR SEVERAL VIEWS

The above mentioned and other objects and advantages of the present invention and a better understanding of the principles and details of the present invention will be evident from the description taken in conjunction with the appended drawings.

The drawings constitute a part of this specification and include exemplary embodiments of the present invention, which may be embodied in various forms. It is to be understood that in some instances various aspects of the invention may be shown as exaggerated, reduced, or enlarged or otherwise distorted to facilitate an understanding of the present invention.

In the drawings appended hereto:

FIG. 1 is a side view of the present invention.

FIG. 2 is a top view of the present invention.

FIG. 3 is a front view of the present invention.

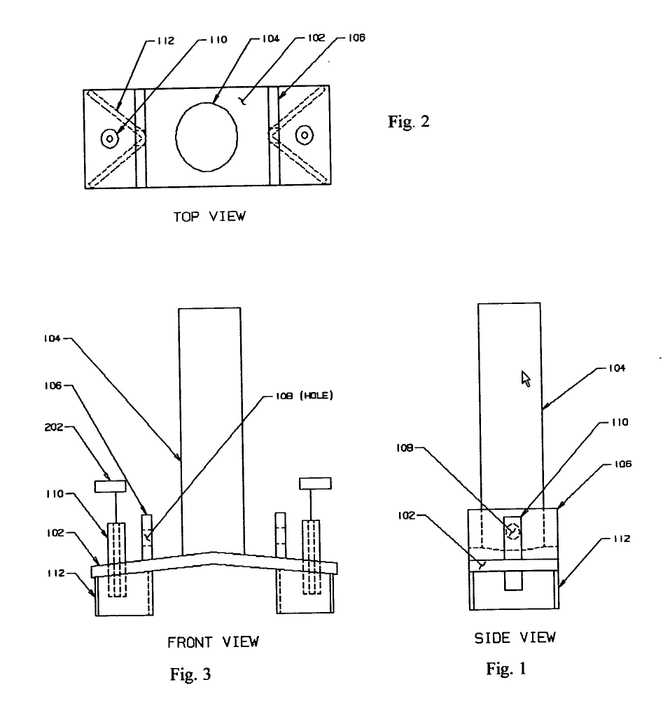

In the accompanying drawings, like elements are given the same or analogous references when convenient or helpful for clarity. The same or analogous reference to these elements will be made in the body of the specification, but other names and terminology may also be employed to further explain the present invention.

### GENERAL DESCRIPTION OF THE INVENTION, DETAILED DESCRIPTION OF PREFERRED EMBODIMENTS OF AND BEST MODE FOR CARRYING OUT THE PRESENT INVENTION

The present invention relates to electrodes and electrode holders for use on animals in Bioelectrical Impedance Analysis (BIA) and other electrical measurements. The electrical measurements may be directed to any of a number of areas of electrical activities either of endogenous or exogenous origin. The preferred electrodes are for use on cattle and/or their carcasses, but may be used in connection with a wide variety of animals. The electrodes systems are intended to overcome problems in the prior art as noted above. They will provide a defined distance between the contact points of the electrodes. The electrodes and their holders are designed to provide to provide accurate and reproducible measurements.

The present invention may be used and/or adapted for use in any Bioelectrical Impedance System.

The electrodes may have attachment clips of various known designs.

The system is not limited to hard wired transmission of its power voltage or signals.

As shown, the electrode holder includes a deck 102 which has a handle 104. A protective partition 106 which may have an opening 108 guards the upper portion of the electrode attachment 110 which may be adapted to receive a hypodermic needle or other needle, probe, solid wire, and/or syringe (not shown).The length and gage of the wire, needle or the like is as appropriate to the specific animal, carcass or use as are the specific materials of construction of the needle, wire or probe. The lower end of attachment 110 is adapted to secure a hypodermic needle (not shown). The lower end of attachment 110 is protected by a v-shaped shield 112 which prevents rocking of the needle and assists in controlling the depth of penetration. Holes 108 allow for the attachment of clips and leads.

For a further understanding of the nature, function, and objects of the present invention, reference should now be made to the following detailed description taken in conjunction with the accompanying drawings. Detailed descriptions of the preferred embodiments are provided herein, as well as, the best mode of carrying out and employing the present invention. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure, or manner. The practice of the present invention is illustrated by the following examples, which are deemed illustrative of both the process taught by the present invention and of the results yielded in accordance with the present invention.

Turning now to matters of function and operation in addition to structure, the electrode holder may have a hypodermic needle with or without caps and may be of the screw on, snap-on or quick release type.

The handle on the top of the electrode holder makes it easier to hold on and control the electrode holder.

The cattle or bovine carcass embodiment of the present invention may be used to measure the amount of lean meat and/or the amount of fat. The present invention, to be more specific, can be utilized to measure, or to be a part of a system to measure or evaluate such parameters as total body water, extra and intra-cellular fluid, plasma, lean muscle mass, fat, the extent of marbling, percentage of saleable retail cuts, fat trim yield, percentage fat trim, yield grade, quality grade, percentage saleable meat yield, phase angles, and general, overall health.

Any type of needle, probe, wire or the like can be attached to the electrode holder.

A needle electrode holder may be used to permit and/or perform tests on live animals or carcasses. In particular, the present invention may be used in disease prediction, preventative analysis, and in the detection of contamination

Well known fast needle exchange systems such as the “Luer lock” or other similar systems may be used to attach the needle electrodes to the bulkhead. See U.S. Pat. Nos. 5,637,101 and RE 038,964.

A tetra-polar system may be employed in connection with the present invention.

The electrode/needle holder provides for the attachment of alligator clips or similar electrode attachment clips. These bovine electrodes or penetrating electrodes can be called “BIA Bovine Penetrating Electrodes.

The holder has a platform structure on the bottom to control the depth of penetration as well as to control or limit rocking motion of the holder and of the electrodes or probes.

The holder and its electrodes may be sterilized in a bath with a temperature higher than 180° F. or otherwise in accordance with the current industry standards

The Plexiglas structure of the electrode holder along with providing for good visibility of and within the holder also provides for cleaning and the detection of any problems with the cleaning. Single or multiple units containing sterile cleaning fluid may be used to clean the electrode holder in accordance with current industry standards

In operation, the measurements may be made in less than 30 seconds on live animals and less than 7 seconds on carcasses with no application of cream or gel to the carcasses.

The present invention may be used:
(1) in feedlot operations,
(2) to determine or predict the grades of meat likely to be produced such as “prime”, “choice” and the like,
(3) as a part of the overall determination of body composition,
(4) to predict disease,
(5) in preventative analysis,
(6) in the detection of contamination,
(7) in slaughterhouse or abattoir operations, and
(8) in meat processing operations

The present invention may be used to predict certain illnesses by the proper application of phase angle shifts as well as direct impedance measurements.

The present invention may utilize retractable or “spring shot” needles which will allow for the administration of vaccinations and antibiotics and the like through the electrode needles. The present invention is intended to use and hold penetrating electrodes and may in addition to or as a separate device may utilize additional and/or separate injection devices

### Alternatives and Alternative Embodiments

While throughout this description, we have referred to various materials, chemicals, and apparatus as being presently preferred, it will be clear to one skilled in the art that other materials, chemicals, apparatus, methods, processes, steps and embodiments may be employed which will also provide the advantages as herein set forth in connection with the present invention. The present invention is not limited to the representative examples disclosed herein. Moreover, the scope of the present invention covers conventionally known variations and modifications to the system and the components described herein, as would be known by those skilled in the art. Such variations and equivalents are intended to be within the scope of the present invention. Accordingly, the invention is to be broadly construed and is to be limited only by the scope and spirit of the claims appended hereto.

To provide a description of the present invention that is both concise and clear, various examples of ranges have been set forth herein and in all cases should be read as though expressly identified with the phrase “including all intermediate ranges and combinations thereof”. Examples of specific values (e.g., ohms, ° C., μm, kg/L, volts, amps, current, intensity, etc.) that can be within a cited range by the reference to “including all intermediate ranges and combinations thereof” include 0.000001, 0.00001, 0.0001, 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, 1.0, 1.1, 1.2, 1.30, 1.31, 1.32, 1.33, 1.34,1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58, 1.59, 1.60, 1.61, 1.62, 1.63, 1.64, 1.65, 1.66, 1.67, 1.68, 1.69, 1.70, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0, 5.1, 5.2, 5.3, 5.4, 5.5, 5.6, 5.7, 5.8, 5.9, 6.0, 6.1, 6.2, 6.3, 6.4, 6.5, 6.6, 6.7, 6.8, 6.9, 7.0, 7.1, 7.2, 7.3, 7.4, 7.5, 7.6, 7.7, 7.8, 7.9, 8.0, 8.1, 8.2, 8.3, 8.4, 8.5, 8.6, 8.7, 8.8, 8.9, 9.0, 9.1, 9.2, 9.3, 9.4, 9.5, 9.6, 9.7, 9.8, 9.9, 10.0, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 275, 300, 325, 350, 375, 400, 425, 450, 475, 500, 525, 550, 575, 600, 625, 650, 675, 700, 725, 750, 775, 800, 825, 850, 875, 900, 925, 950, 975, 1000, 1050, 1100, 1150, 1200, 1250, 1300, 1350, 1400, 1450, 1500, 1600, 1700, 1800, 1900, 2000, 3000, 4000, 5000, 6000, 7000, 8000, 9000, 10,000, or more and so forth.

The above conventions may be understood by means of a number line a common element of elementary mathematics. It can be constructed by marking off two points: zero (the origin) and one (1). The distance from 0 to the point 1 is called the unit segment. The distance between all consecutive whole numbers is the same. When measurements fall somewhere between whole numbers. we may describe the situation in terms of a fractional length or in decimal terms of tenths, hundredths, thousandths and so forth. For example, if a measurement falls between 4 and 5, we may find that it is closer to 4.3 than 4.4. If we want more precision (and it is appropriate), we may continue to “zoom in” in which case we move more decimal places to the right. For numbers less than 5 in the relevant place one may round down and for numbers greater than 5 one may round up. When the relevant place contains a 5, the rule is to round so that the last nonzero digit is an even number. Whenever a range is given herein the above rules are intended to apply and the range is intended to cover all points on the number line from the lowest number to be rounded to the bottom of the range to the highest to the highest number to be rounded to the top of the range.

General ranges and the usual definitions for significant figures for each type of unit (e.g., ohms, %, ° C., μm, kg/L), are contemplated. Examples of values that can be within a cited percentage range, as applicable, include 0.001% to 100%, including all intermediate ranges and combinations thereof. Examples of values that can be within a thickness range (e.g., coating and/or film thickness upon a surface), as applicable, in micrometers (“μm”), that can be within a cited range include of 1 μm to 2000 μm, including all intermediate ranges and combinations thereof. Similar examples may be understood to apply to all of the units and systems of units mentioned above, such as ohms and the like or otherwise discussed below.

The following comments are intended to apply to all units and their conversions to whatever system of units including but not limited to length (m), mass (kg), time (s), speed (m/s),including but not limited to angular frequency or velocity (radian/second), resistance (ohm), reactance (ohms), impedance (ohms) capacitance (farads), charge (coulomb), current (ampere), electromotive force (volt), work or energy (joule), force (Newton), frequency (Hertz), inductance (Henry), magnetic field (B, Tesla), Magnetic flux (Weber), potential (volt) power (waft), etc.

Specific units from one or more of the following systems may be used including but not limited to S.I., m.k.s. practical units; Gaussian units; Heaviside-Lorentz units; electrostatic units, and/or electromagnetic units.

In addition to the standard units the micron (μ=10⁻⁶ m) and Angstrom (Å=10⁻¹⁰ m) are frequently used and may be used herein.

### SUMMARY

An electrode holder comprising a deck member with handle supporting a pair of electrodes to which hypodermic syringe and needle may be connected and which may act as electrodes in a BIA system.

It is noted that the embodiment described herein in detail for exemplary purposes is, of course, subject to many different variations in structure, design application, and methodology. Because many varying and different embodiments may be made within the scope of the inventive concepts herein taught, and because many modifications may be made in the embodiment herein detailed in accordance with the descriptive requirement of the law, it is to be understood that the details herein are to be interpreted as illustrative and not in a limiting sense. It will be understood in view of the instant disclosure, that numerous variations of the invention are now enabled to those skilled in the art. Many of the variations reside within the scope of the present teachings. It is not intended to limit the scope of the invention to the particular forms set forth, but on the contrary, it is intended to cover such alternatives, modifications, and equivalents as may be included within the spirit and scope of the teachings of the present invention. Accordingly, the invention is to be broadly construed and is to be limited only by the spirit and scope of the claims appended hereto.

What is claimed is:

1. An electrode holder comprising a deck member with handle of said deck supporting a pair of electrodes to which hypodermic syringe and needle may be connected and which may act as electrodes in a bioelectrical impedance analysis system or in connection with other electrical measurements.

2. The electrode holder of claim 1 wherein the deck supports a protective partition having a hole therein to permit the attachment of clips or leads and which guards the upper portion of the electrode attachment member which may receive a hypodermic syringe.

3. The electrode holder of claim 1 wherein the lower end of the attachment is adapted to receive a hypodermic needle, other needles, probes, wires or other penetrating devices.

4. The electrode holder of claim 1 wherein the lower end of the attachment is protected by a shield or structure which prevents rocking of
(1) the electrode holder
(2) the penetrating probe or device, and
(3) assists in controlling the depth of penetration.

5. The electrode holder of claim 1 wherein the attachment of the penetrating electrode is of the quick release type.

6. A method of bioelectrical impedance analysis comprising:
[a] providing a means of providing a voltage difference across two or more electrodes;
[b] maintaining said electrodes in a fixed spatial relation and in good electrical contact by penetrating with a penetrating electrode the skin or tissue of the animal and/or animal carcass on which said measurements are to be made; and
[c] measuring the impedance of said animal or animal carcass in the region of the penetrating electrode.

7. The method of claim 6 wherein the electrodes are spatially fixed by a deck holding a quick release electrode holder.

8 The method of claim 6 wherein the said deck holds two or more electrodes.

9. The method of claim 6 wherein the deck has a handle.

10. The method of claim 6 wherein the upper portion of the electrode attachment may receive a hypodermic syringe and/or other injection device.

11. The method of claim 6 wherein the upper portion of the electrode attachment is guarded by a protective partition.

12. The method of claim 6 wherein the lower end of the attachment is adapted to secure a hypodermic needle electrode.

13. The method of claim 6 wherein the lower end of the attachment is protected by a shield which prevents rocking of the penetrating electrode and assists in controlling the depth of penetration of the penetrating electrodes.

14. The method of claim 6 wherein the electrode needles are caused to penetrate into the animal or carcass to permit the measurements.

15. The method of claim 6 wherein the electrode needles may deliver vaccines, antibiotics and other drugs.

16. The method of claim 6 wherein the electrode holder and electrodes may be used in making other electrical measurements.

17. The method of claim 6 in which the voltage difference is established by wireless means.

18. The method of claim 6 in which the voltage difference is established by remote means.

19. The method of claim 6 wherein other electrical measurements are made in addition to BIA.

20. The method of claim 6 wherein the voltage difference in established by remote, wireless means.
